(19) United States
(12) Patent Application Publication
(10) Pub. No.: US 2006/0078212 A1
(43) Pub. Date: Apr. 13, 2006

(54) Embedding a watermark in a coded signal

(75) Inventor: Gerrit Cornelis Langelaar, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., BA Eindhoven (NL)

(21) Appl. No.: 10/542,892

(22) PCT Filed: Dec. 16, 2003
(86) PCT No.: PCT/IB03/06179

§ 371 Date: Jul. 20, 2005

(30) Foreign Application Priority Data
Jan. 23, 2003 (EP) 03100140.7

(51) Int. Cl. G06K 9/36; H03M 7/40

(52) U.S. Cl. 382/246; 341/67

(57) ABSTRACT

Method and arrangement for water(re)marking a compressed video signal by modifying selected DCT coefficients. To avoid that the bitrate is thereby reduced too much, selected variable-length codewords are represented by escape codes. In order to avoid that ESC codes increase the bitrate too much (an ESC code is 7-21 bits longer than the corresponding VLC word), the bitrate is controlled in units of small data chunks. While a VLC is processed, a table is filled with candidate ESC codes. The bitrate controller tries to make the difference between original and processed data chunks zero by re-encoding one VLC into an appropriate ESC code.

This invention relates to watermarking a coded signal, particularly, but not limited to, a method of watermarking a compressed video signal.

Watermarking of coded signals, particularly compressed coded signals, is achieved with a fixed size of compressed data which forms part of a larger datastream. In order to add a watermark a few code words in the compressed data are changed. This results in a change of the data size. In order to merge the re-encoded data, which may be said to be in a data chunk, into the original datastream, the data size must be the same as the original fixed size, in order to prevent problems with synchronisation and syntax correctness etc.

A known method of embedding a watermark in a compressed media signal is disclosed in F. Hartung and B. Girod; “Digital watermarking of MPEG2 coded video in the bitstream domain”, published in ICASSP, vol 4, 1997 pp 2621-2624. In this prior art publication, the media signal is a video signal, the signal samples of which are discrete cosine transform (DCT) coefficients obtained by subjecting the image pixels to a DCT. The watermark is a DCT transformed pseudo-noise sequence. The watermark is embedded by adding the DCT transformed noise sequence to the corresponding DCT coefficients of the video signals. The coefficients with a value of zero of the MPEG-coded signal are not affected.

A problem of the prior art watermark embedding scheme is that modification of DCT coefficients in an already compressed bitstream changes the bit rate, because the DCT coefficients are represented by variable-length code words. An increased bit rate is usually not acceptable, for the reasons mentioned above. The prior art embedder therefore checks whether transmission of the watermarked coefficient increases the bit rate, and transmits the original coefficient in that case. But also, reduction of the bit rate is not desired. In MPEG systems, for example, the change of the bit rate may result in overflow or underflow of buffers in the decoder, and change the position of timing information in the bitstream.

It may be necessary to increase the size of the data chunks in order to equalise with the original fixed size of the datastream. The only way to get data expansion of this type in small data chunks is re-encoding variable length codes (VLCs) as Escape codes. The process known as bit stuffing, i.e. adding additional bits to “pack out” the data chunk to the required size, is not possible, because start codes are not present in most data chunks. A problem is that the result of Escape coding is not predictable. For instance, using MPEG re-encoding the smallest DCT-VLC as an Escape code results in a 21-bit increase in the number of bits. Re-encoding the largest DCT-VLC as an Escape code results in a bit increase of 7-bits. Re-encoding the other DCT-VLCs as Escape codes generates increases between 7 and 21 bits. Consequently, an increase of between 1 and 6 bits is impossible to generate and increases of more than 21-bits must be generated by re-encoding multiple DCT-VLCs as Escape codes. Furthermore, it is impossible to know in advance which VLCs are present in the data chunk to re-encode as Escape codes. In the worst case, there is no suitable VLC present. In order to obtain a bit increase of 300-bits, a combination must be found of a number of VLCs which coded as Escape codes together exactly generate this amount of bits. This provides a particularly difficult problem to solve. It can not be determined in advance how long it will take to find the right combination. In order to solve this problem using a search algorithm in real-time requires a very powerful processor or an enormous amount of memory. Both of these possible solutions are unacceptable requirements in the field of consumer electronics where this problem is encountered, because of costs.

Further background information can be found in the applicant's unpublished co-pending International Patent Application IB02/02737 (Attorney's docket PHNL010493EPP).

Consequently, an alternative solution to the problem of matching data sizes is required.

It is an object of the present invention to address the above mentioned disadvantages.

According to a first aspect of the present invention, a method of processing a compressed media signal is provided, in which samples of said media signal are represented by variable-length code words (VLCs), the method comprising the steps of:
decoding the VLCs of a sample;
modifying a plurality of said decoded VLCs in accordance with a given signal processing algorithm;
encoding the modified decoded VLCs into modified VLCs by a first coding method;
encoding the modified decoded VLCs into at least one length of code by a second coding method;
for each of the plurality of modified VLCs, selecting the modified VLC coded by the first or second method that has a length closest to the length of the corresponding unmodified VLC, and
combining the selected modified VLCs and any unmodified VLCs.

Preferably, the first coding method is a standard VLC coding method. Preferably, the second coding method is an Escape coding method.

The second coding method may be another watermarking algorithm that may increase the bit size of a VLC or may be an algorithm that simply adds noise to VLC coefficients to increase the bit size thereof.

Preferably, the modified encoded VLCs are encoded into a plurality of lengths using the second coding method, preferably the second coding method provides codes from 7 to 21 bits longer than the first coding method.

The signal processing algorithm is preferably a watermark algorithm.

Preferably, the decoded VLCs are only modified under certain criteria, said criteria affecting the visibility of an applied watermark.

The method may involve inserting bits into the encoded modified VLCs, preferably by bit-stuffing techniques, preferably for the modified VLCs coded by the first coding method.

The method preferably involves the treatment of packets of VLCs, preferably 188 byte packets, individually, without reference to other packets.

According to another aspect of the invention a signal processing device for a compressed media signal comprises:
a decoder operable to decode samples of a compressed media signal represented by variable-length code words (VLCs);
means for modifying a plurality of the decoded VLCs in accordance with a given signal processing algorithm;
a first encoder operable to encode the modified decoded VLCs into modified VLCs by a first coding method;
a second encoder operable to encode the modified decoded VLCs into modified VLCs by a second coding method;
memory means operable to buffer the modified decoded VLCs from the fist and second encoders; and
a controller operable to select the modified VLC from either the first or second encoder closest in length to an unmodified VLC, for each of the plurality of modified VLCs.

The controller is preferably a bit-rate controller.

The signal processing device is preferably a watermarking device.

For a better understanding of the invention and to show how the same may be brought into effect, specific embodiments of the present invention will now be described, by way of example, with reference to the accompanying drawings, in which:

FIG. 1 is a schematic diagram showing a scheme for re-marking video data coded in an MPEG2 transport stream (TS) format;

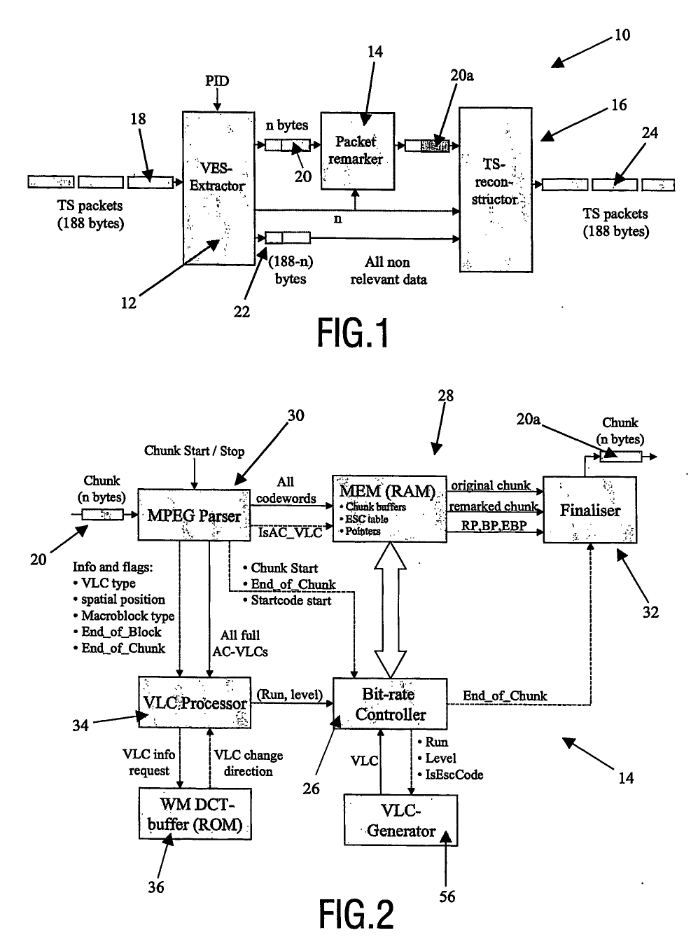

FIG. 2 is a schematic diagram of the packet remarker shown in FIG. 1; and

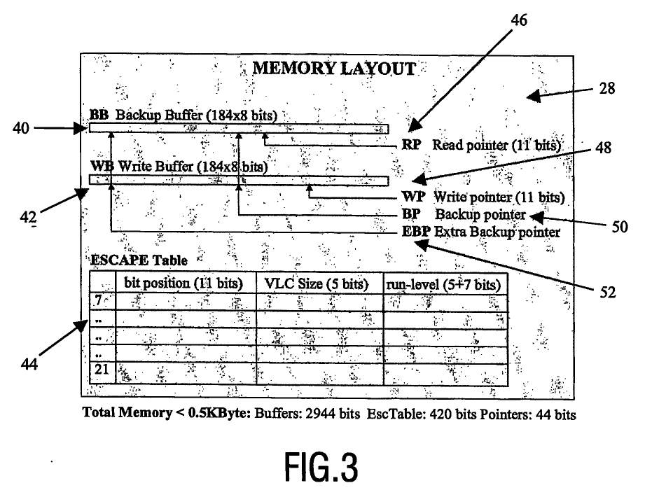

FIG. 3 is a schematic diagram of a RAM memory element of the package remarker shown in FIG. 2.

The following method describes an algorithm for inserting a “no more copies” watermark in a (possibly already watermarked) video signal in MPEG2 transport stream (TS) or program stream (PS) format. Further information concerning the MPEG2 video compression standard can be found at:

[ISO96:1] ISO/IEC 13818:1:1996(E), “Information Technology—Generic Coding of Moving Pictures and Associated Audio Information: Systems”, Video International Standard, 1996, and

[ISO96:2] ISO/IEC 13818:2:1996(E), “Information Technology—Generic Coding of Moving Pictures and Associated Audio Information: Video”, Video International Standard, 1996.

In Applicant's International Patent Application WO-A-02/060182 (hereinafter referred to as “VWM specification”), the basic principal of “run-merging” used by the watermark embedding technique is described.

The problem of using the original algorithm on a transport stream is that it either requires a large amount of memory or the bit-rate control needs to be executed on small packets. As this would decrease the effectiveness of the embedding substantially, the algorithm described below has a far more sophisticated bit-rate control, using 3 tools: the run-merge algorithm (which decreases the amount of bits), the use of Escape-coding and the addition of stuffing bits (both of which increase the amount of bits). In this way it is possible to do an effective embedding with bit-rate control per packet at an acceptable cost in terms of memory and computational complexity. As the packets in a transport stream are smaller than those for a program stream (188 bytes vs. 2 Kilobyte), we focus on a solution for transport streams (TS). The PS solution is derived from the TS solution by dividing the PS packets into sub-packets of 188 bytes and processing the sub-packets in the same way as the TS-packets.

The TS/PS algorithm described below has the following features:
it uses the standard run merge technique with adapted bit rate control;
it remarks each 188 byte TS packet individually without reference to other TS packets to avoid de-multiplexing and re-multiplexing;
it remarks only one video elementary stream (VES) from a range of video streams in TS, selected by one particular packet identifier (PID) (extension to parallel remarking is possible).

The main problem in adapting Video Elementary Stream (VES) remarker from the VWM Specification referred to above to the case of TS streams is that either it requires a very large amount of memory, or it requires bit-rate control (making sure that the remarked stream has the same size as the original stream) per TS packet. The former is prohibitive because of a large increase of silicon-cost. In the latter case the bit-rate control needs to be much more complicated than in the original VES solution in order to achieve a sufficient embedding strength. The run-merge technique underlying the remarker has a strong tendency to decrease the length of the stream. The bit-rate control for the VES remarker uses insertion of stuffing bits to again increase the length of the stream to make it the same size as the original stream. Within one TS packet there is only very limited room for insertion of stuffing bits. This implies that additional tools are needed to increase the length of the stream. For this, the use of Escape-coding is introduced. This is a versatile tool, as it gives the possibility to replace each of the VLCs in the remarked stream by an Escape-code. The difficulty of this versatility is that the decision whether a run-level pair is VLC-encoded or Escape-coded creates a very difficult combinatorial problem. The bit-rate control algorithm described in the next section is a sub-optimal solution with a strongly reduced complexity relative to the optimal solution.

As depicted in FIG. 1, a remarker 10 consists of three basic blocks: the VES (Video Elementary Stream) extractor 12, the packet remarker 14 and the TS reconstructor 16.

Operation of the elements is as follows.

The VES extractor 12 splits a TS packet 18 into two smaller chunks, a chunk 20 containing the VES-bytes of the video stream corresponding with the PID that has to be remarked and a chunk 22 with all other data, e.g. TS header, PES header, audio bytes, video bytes of other PIDs, etc.

The packet remarker 14 adds the remark to the chunk 20 with VES bytes in such a way that a watermarked output chunk 20a has exactly the same number of bits as the original input chunk 20. A detailed explanation of the workings of the packet remarker 14 is given below.

The TS reconstructor 16 recombines the two chunks 20a and 22 to build a valid remarked TS stream.

The packet remarker 14 will now be described in more detail.

As explained in the previous section, the main difference compared to a VES remarker is the more complicated bit-rate control. Therefore, in this section, we explain the workings of the packet remarker 14, with an emphasis on a bit-rate controller element 26. After that we explain in full detail the workings of all components of the packet remarker.

FIG. 2 presents the basic blocks of the packet remarker 14. To realise the adapted bit-rate control, the remarker 14 has been designed around a central piece of RAM memory 28. All operations are carried out on information stored in this memory 28. The most complex aspect of the embedding is the bit-rate control. This induces a strong interaction between the bit-rate controller 26 and the memory 28, but also an MPEG parser 30 and a finaliser 32 operate upon the memory.

Upon reception of an incoming chunk 20, the MPEG parser 30 extracts all AC-VLCs. These are sent to a VLC processor 34 together with associated information, like MPEG encoding parameters and the spatial position in the frame of the corresponding macro-block. The VLC processor 34 contains the core run-merge technique, as described in the VWM specification above. It decodes the incoming luminance AC-VLCs to run-level pairs and subsequently this stream of run-level pairs is changed, based on the information in a WM DCT buffer 36 (containing the change direction for the AC-VLCs, as derived from the spatial watermark pattern). The resulting run-level pairs are then sent to the bit-rate controller 26. Note that, due to the application of the run-merge technique, there will be a smaller number of run-level pairs coming out of the VLC processor 34 than came into it. The bit-rate controller 26 encodes the watermarked run-level pairs and sends them to the memory 28. This is done in a way (as explained in the paragraph below) so as to maximise the part of the remarked chunk 20a that is as big as the corresponding part of the original stream 20. The finaliser 32 then creates a remarked chunk 20a of the same size as the original by replacing this corresponding part in the original 20 stream by its remarked counterpart. The resulting chunk 20 is then sent to the TS reconstructor 16 (see FIG. 1).

Let us explain the approach taken by the bit-rate controller 26. The overall bit-rate control strategy is based on keeping the size of the remarked version 20a as close as possible to the original one 20. One of the ways to achieve this is to add stuffing bits before a start-code, in the same way as for the VES remarker described in the VWM Specification. However, the main way is by use of Escape-coding. A copy of the original chunk 20 is stored in the memory 28 (in a so-called “backup buffer” 40, see FIG. 3). The remarked version of the chunk is stored in a so-called “write buffer” 42 in FIG. 3. In the write buffer 42 we place two pointers, indicating the start and the end of a piece of the watermarked chunk 20a which has exactly the same size as the corresponding part of the unwatermarked chunk 20. Upon reception of a run-level pair, the VLC of the run-level pair is computed. It is added to the write buffer 42 in memory 28. Moreover, in an “Escape-table” 44 in memory 28 an entry is created, indexed by the difference in length between the VLC (size between 3 and 17 bits) and the corresponding Escape-code (fixed size of 24 bits). Now, the difference in length between the write buffer 42 and the backup buffer 40 is computed.

If the Escape-table 44 contains an entry for which the difference in size between the VLC and the Escape-code is equal to the difference in buffer lengths, then the corresponding VLC is replaced by the Escape-code. Note that now the buffers 40, 42 contain two corresponding parts of exactly the same size. Hence, the two pointers in the write buffer 42 need to be updated.

If the difference in length between the two buffers 40, 42 is too large to be completely removed, in the way as described above, the bit-rate controller 26 will try to reduce the difference in length, also by replacing VLCs by Escape-codes. To reduce the number of changes, the replacement with the largest increase in code-size is used.

Next we explain all components in full detail.

MPEG Parser

The MPEG parser 30 has two tasks. Its first task is to partially interpret the MPEG stream to gather information about the luminance VLCs (I, P and B frames). It collects the following information:
top (x, y )-co-ordinates of source macro-block
position of source 8×8 block in corresponding macro-block
scan position VLC in the 8×8 block
scan type (zigzag, alternating)
VLC code type (field, frame)
Quantization step size
VLC size
Current Picture type
Current macro-block type

Furthermore it searches for bit-stuffing locations. These are the locations before the start codes (indicated by the variable “start-code start” and communicated by the parser 30 to the bit-rate controller 26). The parser 30 also indicates when a chunk starts or ends.

Its second task is to extract AC-VLCs representing luminance and chrominance AC-DCTs from the MPEG stream. The AC-VLCs are passed on to the VLC processor 34 together with the information about the VLCs. All original MPEG code-words are also passed on to the memory (RAM) block 28. Each code-word is stored in the memory 28 together with a flag indicating whether the code-word is a full AC-VLC or not. Only complete VLCs are passed on to the VLC-processor 34; VLCs crossing the boundary of a chunk are not taken into account by the VLC processor 34.

VLC Processor

In the VLC-Processor 34 the actual embedding takes place. It receives the AC-VLCs, both from the luminance and the chrominance components. The chrominance AC-VLCs are just decoded and the resulting run-level pairs are passed on to the bit-rate controller 26. The luminance AC-VLCs are processed to embed the watermark. This is done in the same way as in the VES remarker described in the VWM Specification above. A brief description is given below and the interested reader is referred to the VWM Specification document for more detailed information and figures. Starting with VLCs representing run-level pairs of luminance AC-DCT coefficients, the following tasks are performed:

1. Decode VLCs to run-level pairs;

2. Select candidate run-level pairs from the luminance DCT coefficients. A candidate run-level pair is a run-level pair with a level equal to −1 or 1;

3. Calculate WM buffer address of the DCT change direction that corresponds with the VLC. Fetch the change direction from the WM-DCT buffer 36;

4. Selectively merge candidate (run, level) pairs if the following 4 conditions are satisfied:

4.a The level plus the corresponding change direction in the WM DCT buffer 36 equals 0, i.e.:

((level=−1) && (WM buffer=+1)) OR ((level=+1) && (WM buffer=−1))

4b. The merge will not affect the visual quality severely according to a simple human visual model.

5. Pass on all processed run-level pairs (for Y, U and V) to the bit-rate controller 26.

The conditions 4.b, 4.c and 4.d control the visibility of the watermark. There are 3 DCT energy thresholds for I,P and B pictures: E_{I}, E_{P} and E_{B}. These thresholds can limit the number of changes further to 0, 1 and 2 as a function of the quantization step. Upon End_of_Block or End_of_Chunk, the VLC processor 34 is reset.

WM-DCT Buffer (ROM)

The WM-DCT buffer 36 is described in full detail in the VWM specification.

Memory (RAM)

The RAM memory 28 is depicted in FIG. 3. It consists of the Backup Buffer 40 and the Write Buffer 42 (both of size 184 bytes) and an Escape-table 44. The MPEG parser 30 stores the original VES data of an incoming chunk 20 in the Backup Buffer (BB) 40. A watermarked version is generated in the second buffer, the Write Buffer 42 (WB). The buffers 40, 42 are filled from the left to the right. Both buffers have a pointer at the first position after the last written bit, named a Read Pointer 46 (RP, for the Backup Buffer 40) and a Write Pointer 48 (WP, in the Write Buffer 42). The MPEG parser 30 sends all data to the Backup Buffer 40. It also sends all data except the full AC-VLCs to the Write Buffer 42. The full AC-VLCs for the Write Buffer 42 are generated by the bit-rate controller 26. The memory contains two pointers, named Backup Pointer (BP) 50 and Extra Backup Pointer 52 (EBP). In the Write Buffer 42, these pointers indicate the end and the start, respectively, of the watermarked chunk that has exactly the same size as its unwatermarked counterpart. These pointers are set by the bit-rate controller. The part in the Write Buffer 42 between the Backup Pointer 50 and the Write Pointer 48 indicates the part which has been watermarked, but which does not yet have the same size as the corresponding part in the Backup Buffer 40. Usually, the Extra Backup Pointer 52 points to the start of the Write Buffer 42. It shifts to the right if the size of the initial part (between the start of the buffer and a start-code in the buffer) of the chunk increases by the run-merge technique (see the section headed Start Code Start, sub-section 1b below).

The Escape-Table 44 contains 15 rows ranging from 7 to 21. Each row is empty or it describes a certain VLC from the Write Buffer 42. If row i (i ranging from 7 to 21) is not empty, a VLC exists that will increase the write buffer 42 with i bits when this VLC is replaced by an Escape-code. The Escape-table 44 is administered by the bit-rate controller 26. The bit-rate controller 26 will occasionally replace a VLC from this table by an Escape-code to control the bit-rate.

Bit-rate Controller

In this section we will explain the operation of the bit-rate controller 26 in full detail. Between the explanation of the actions of the bit-rate controller 26, we have placed “timing notes”, listing the order in which actions of different modules need to be executed.

There are four different commands coming from different modules, based on which the bit-rate controller chooses its next action:
Chunk Start from the MPEG parser 30;
New run-level pair from the VLC processor 34;
Start-code start from the MPEG parser 30;
End of Chunk from the MPEG parser 30;

The actions taken by the bit-rate controller 26 on these commands are detailed in the sections below.

Chunk Start

In response to the “Chunk Start” command, the bit-rate controller 26 is reset to its initial position. This encompasses:

1. Labelling all entries of the Escape-table 44 “empty”.

2. Setting the 4 pointers RP 46, WP 48, BP 50 and EBP 52 to 0.

New run-level pair

The bit-rate controller 26 receives the run-level pairs from all (chrominance and luminance) AC-VLCs. For each of these run-level pairs (r,l), it performs the following 6 steps:

1. Request from a VLC generator the VLC v of run-level pair (r,l).

2. Update the Escape-table 44 as follows. Compute the difference Δ_{C} in size between the Escape-code (which is always 24 bits) and the VLC: Δ_{C}=size( Escape-code)—size(v).

Next, row Δ_{C} of the Escape-table 44 is filled:

bit-position=WP 48;

VLC-size=size(v);

run-level=(r,l).

3. Write VLC v into the Write Buffer 42. Update the write pointer 48 accordingly.

Timing Note:

I. The MPEG parser 30 sends the original VLC to the memory 28, where it is written in the Backup Buffer 40 (RP 46 is updated).

II. Next the VLC is decoded by the VLC processor and the—possibly merged—run-level pair is sent to bit-rate controller 26.

III. The bit-rate controller 26 sends the remarked VLC to the memory 28, where it is written in the Write Buffer 42 (WP 48 is updated).

4. Try to make the length of the Write Buffer 42 and the Backup Buffer 40 exactly equal. This can be done if:
The number of VLCs that has been Escape-coded so far in this chunk is smaller that the maximum allowed (EM)
The difference in length Δ_{B} between the Write Buffer 42 and the Backup Buffer 40 is between 7 and 21: 7≦Δ_{B}≦21
Row Δ_{B} of the escape table 44 is not empty
If these conditions are satisfied, then take the following actions:
Replace the VLC in the Write Buffer 42, as indicated in row Δ_{B} of the Escape-table 44, by its Escape-coded version (which the bit-rate controller 26 requests from the VLC generator 56), and shift all entries following that VLC in the Write Buffer 42 Δ_{B} positions to the right.
Update the Escape-table 44:
All bit positions in the Escape table 44 larger than the one of the VLC just replaced are increased by Δ_{B}
Clear row Δ_{B} and label it “empty”
Update the Write Pointer 48 (now, WP=RP 46)

5. Try to make the length of the Write Buffer 42 and the Backup Buffer 40 as small as possible. This is done if:
The number of VLCs that has been Escape-coded so far in this chunk is smaller that the maximum allowed (EM)
The difference in length between the Write Buffer 42 and the Backup Buffer 40 (Δ_{B}) is greater than 21: Δ_{B}>21

If these conditions are satisfied, then search in the Escape-table 44 from row 21 down to row 7 for the first non-empty row that has a bit position greater than or equal to the backup pointer BP 50 (this last condition is necessary to avoid illegal MPEG syntax with non byte-aligned start-codes). If such a row exists, it is defined as row i, and the following actions are executed
Replace the VLC described on row i of the Escape-table 44 in the write buffer 42 by its escape-coded version, which the bit-rate controller 26 requests from the VLC generator 56, and shift all entries in the write-buffer 42 following that VLC over i positions to the right.
Update the Escape-table 44 as follows:
All bit positions in the Escape table 44 larger than the one of the VLC just replaced are increased by i
Clear row i and label it “empty”

6. Update the Write Pointer 48 (WP=WP+i)

Update the backup pointer 50. If the Write Buffer 42 and the Backup Buffer 40 have the same length (i.e., if WP 48=RP 46), then the backup pointer is shifted: BP 50=WP 48.

Start-code start

Before a start-code, the bit-rate controller 26 has the possibility to make the size of the Write Buffer 42 and the Backup Buffer 40 equal by adding stuffing bits. Of course, this is only possible if the Write Buffer 42 is shorter than the Backup Buffer 40. If it is larger than the backup buffer 40, then the Extra Backup Pointer 52 is shifted to the position of the Read Pointer 46 (recall that the finaliser 32 uses the part of the chunk between bit position 0 and EBP 52 from the Backup Buffer 42). Summarising, the following steps are carried out:

1a. If the Write Buffer 42 is smaller than the Backup Buffer 40 (i.e., WP48 ≦RP42) Write stuffing bits (value=“0”) into the Write Buffer 42 WB until the write pointer WP 48 equals read pointer RP 46.

1b. If The Write Buffer 42 is larger than the Backup Buffer 40 (i.e., WP>RP), reject remarking of the part of the chunk received so far. That is, update EBP 52 and WP 48:
EBP=RP,
WP=RP.

2. Write the start-code received from the MPEG parser in the Write Buffer 42 and the Backup Buffer 40 and update the pointers WP 48 and RP 46.

3. Update the Backup Pointer: BP 50=RP 46

4. Clear the Escape-table 44 and label all entries “empty”.

Timing Note:

I. The MPEG parser 30 sends the start-code start signal to the bit-rate controller 26.

IIa. EITHER the bit-rate controller 26 writes the appropriate number of stuffing into the Write Buffer 42 and updates the write pointer 48

Ilb. OR The bit-rate controller 26 rejects remarking of the first part of the chunk and updates EBP 52 and WP 48

III. The MPEG parser 30 writes the start-code both in the Backup Buffer 40 and in the Write Buffer 42 and updates the Read Pointer 46 and the Write Pointer 48.

IV. The Bit-rate controller 26 updates the Backup pointer 50 and clears the Escape-table 44.

End of Chunk

Upon receiving the End of Chunk command, the bit-rate controller 26 passes it on to the finaliser 32.

Timing Note:

I. The MPEG parser 26 writes the last complete or incomplete VLC in the Backup Buffer 40 and the Write Buffer 42 and updates the pointers RP 46 and WP 48.

II. End of Chunk command is passed on to Finaliser 32.

VLC Generator

The VLC generator 56 generates VLC codes for run-level pairs (Table B14 and B15 from [ISO96:2] referred to above upon request of the bit-rate controller 26. The bit-rate controller 26 also provides a flag if a normal VLC or an Escape-code is requested.

Finaliser

The Finaliser 32 creates a valid output chunk by combining the Backup Buffer 40 and the Write Buffer 42 in the following way:
bits 0..EBP-1 from the Backup Buffer 40 are copied to the output chunk 20a
bits EBP..BP-1 from the Write Buffer 42 are copied to the output chunk 20a
bits BP..RP-1 from the Backup Buffer 40 are copied to the output chunk 20a

The algorithm described above can easily be extended to deal with program streams (PS) as described in [ISO96:1] referred to above. Only the VES extractor 12 and the TS reconstructor 16 need to be changed (FIG. 2). The packet remarker 14 remains the same.

The VES extractor 12 reads a PS packet and splits it into two smaller chunks, a chunk containing the VES bytes of the video stream and a chunk with all other data, e.g. PS header, Packetised Elementary Stream (PES) header, audio bytes, video bytes of other PIDs etc. The chunk 20 containing the VES bytes is split in sub-chunks of at most 184 bytes. A sub-chunk will never cross a PES or pack boundary. These sub-chunks are offered to the unaltered packet remarker 14.

The TS reconstructor 16 needs to be replaced by a PS reconstructor, which recombines the sub-chunks to build a valid PS stream.

The method of watermarking compressed data streams advantageously provides a solution to avoid the high cost of a large memory or computational cost that would otherwise result.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

The invention can be summarized as follows. Method and arrangement for water(re)marking a compressed video signal by modifying selected DCT coefficients. To avoid that the bitrate is thereby reduced too much, selected variable-length codewords are represented by escape codes. In order to avoid that ESC codes increase the bitrate too much (an ESC code is 7-21 bits longer than the corresponding VLC word), the bitrate is controlled in units of small data chunks. While a VLC is processed, a table is filled with candidate ESC codes. The bitrate controller tries to make the difference between original and processed data chunks zero by re-encoding one VLC into an appropriate ESC code.

1. A method of processing a compressed media signal, in which samples of said media signal are represented by variable-length code words (VLCs), the method comprising the steps of:
decoding the VLCs of a sample;
modifying a plurality of said decoded VLCs in accordance with a given signal processing algorithm;
encoding the modified decoded VLCs into modified VLCs by a first coding method;
encoding the modified decoded VLCs into at least one length of code by a second coding method;
for each of the plurality of modified VLCS, selecting the modified VLC coded by the first or second method that has a length closest to the length of the corresponding unmodified VLC; and
combining the selected modified VLCs and any unmodified VLCs.

2. A method as claimed in claim 1, in which the first coding method is a standard VLC coding method.

3. A method as claimed in either claim 1, in which the second coding method is an Escape-coding method.

4. A method as claimed in claim 1, in which the modified encoded VLCs are encoded into a plurality of lengths using the second coding method.

5. A method as claimed in claim 4, in which the second coding method provides codes of between approximately 7 to 21 bits longer than the first coding method.

6. A method as claimed in claim 1, in which the signal processing algorithm is a watermark algorithm.

7. A method as claimed in claim 6, in which the decoded VLCs are only modified under certain criteria, said criteria concerning the visibility of an applied watermark.

8. The method as claimed in claim 1, which involves inserting bits into the encoded modified VLCs.

9. The method as claimed in claim 1, which involves the treatment of packets of VLCs individually, without reference to other packets.

10. A signal processing device for a compressed media signal comprises:
a decoder operable to decode samples of a compressed media signal represented by variable-length code words (VLCs);
means for modifying a plurality of the decoded VLCs in accordance with a given signal processing algorithm;
a first encoder operable to encode the modified decoded VLCs into modified VLCs by a first coding method;
a second encoder operable to encode the modified decoded VLCs into modified VLCs by a second coding method;
memory means operable to buffer the modified decoded VLCs from the fist and second encoders; and
a controller operable to select the modified VLC from either the first or second encoder closest in length to an unmodified VLC, for each of the plurality of modified VLCs.
